(19) United States
(12) Patent Application Publication
(10) Pub. No.: US 2013/0160704 A1
(43) Pub. Date: Jun. 27, 2013

(54) CRUCIBLE SUPPORT STRUCTURE

(71) Applicants: Marvin LaFontaine, Kingston, NH (US); Keith Vaillancourt, Pelham, NH (US); Patrick Renard, Lunenburg, MA (US); Vorin Hay, Nashua, NH (US)

(72) Inventors: Marvin LaFontaine, Kingston, NH (US); Keith Vaillancourt, Pelham, NH (US); Patrick Renard, Lunenburg, MA (US); Vorin Hay, Nashua, NH (US)

(73) Assignee: GT Advanced Technologies, Merrimack, NH (US)

(21) Appl. No.: 13/336,495

(22) Filed: Dec. 23, 2011

(51) Int. Cl. C30B 11/02; C03B 19/02

(52) U.S. Cl. 117/223; 65/361

(57) ABSTRACT

A crystal growth furnace comprising at least three support pedestals supporting a crucible block and at least one means for stabilizing at least two of the support pedestals is disclosed. The stabilizing means can include support pedestals having a carbon-carbon composite outer layer recessed into the crucible block, a pedestal support system comprising at least one brace for securing at least two of the support pedestals to each other, or both.

### BACKGROUND OF THE INVENTION

1. Field of the Invention

The present invention relates to a crystal growth furnace having at least three support pedestals and at least one means of stabilizing them, as well as to a method of stabilizing the support pedestals.

2. Description of the Related Art

Advances in silicon ingot production processes are an important contributing factor in lowering the overall cost of solar cell production. Solar cells are manufactured using silicon wafers sliced from silicon ingots produced by several production methods using, for example, Czochralski (CZ), heat exchanger (HEM) or directional solidification (DSS) crystal growth furnace systems. DSS furnaces are the most commonly used system to produce silicon ingots because large ingots can be generated and the directional solidification process can be controlled to optimize grain size and segregate impurities out of the molten silicon before it solidifies into a large high quality silicon ingot for silicon wafer production.

The goal of the silicon ingot production process is to maximize the amount of high quality waferable material produced with maximum throughput to lower the overall cost of producing silicon ingots. Since the production of silicon ingots is a batch process, it makes economic sense to process and produce more material per batch by growing even larger ingots to lower the unit cost of the waferable material. Wherein just two years ago the average size of a commercially produced silicon ingot weighed approximately 450 kg (992 lbs), silicon ingots produced today routinely weigh approximately 650 kg (1,433 lbs). As the science and technology advances, the production of silicon ingots weighing more than 800 kg's (1,764 lbs) may be just around the corner.

However, while these larger ingots may result in more waferable material, the sheer size and weight of the silicon being produced presents some production and logistical problems. For example, to produce a 650 kg (1,433 lbs) silicon ingot by the DSS method, silicon feedstock is added to a crucible in a graphite crucible box, placed on a crucible block in the DSS furnace supported from below by typically three support pedestals, and then heated to melt the feedstock. Given the enormous weight of the charge, it is important that the support pedestals are structurally strong enough to prevent their collapse under the weight of silicon to prevent a molten silicon spill or the potential destruction of the newly formed ingot. Support pedestals can be engineered to take into account the weight of a static or “dead” load since the weight of the silicon to be placed in the furnace is known from the onset. However, a “live” load, that is, a load which may be brought on by a sudden lateral movement resulting from, for example, the removal of heavy ingots using lifting equipment or unexpected earthquakes, can be unpredictable. For example, when an earthquake occurs, the energy released creates rapid ground movement or acceleration in the earth's surface. For a given acceleration, the load or lateral force applied to the support pedestals increases as the weight the pedestals carry increases. Therefore, the heavier the crucible charge, the more force will be applied to the support pedestals and the greater the chance of their failure.

As such, there is a need in the industry for a reliable means of stabilizing support pedestals upon which heavy crucible loads rest in a high temperature crystal growth furnace in order to reduce the chance of a catastrophic molten silicon spill or the destruction of a newly formed ingot caused by sudden lateral acceleration force that may cause the support pedestals to fail and collapse.

### SUMMARY OF THE INVENTION

The present invention relates to a crystal growth furnace comprising an inner furnace wall, at least three support pedestals resting on top of the inner furnace wall, a crucible block supported from below by the at least three support pedestals, and at least one means of stabilizing the support pedestals. In one embodiment, the stabilizing means comprises at least three support pedestals having a reinforcing outer layer bonded to an inner core wherein the crucible block comprises at least three counter-bored holes sized and shaped to recess the reinforcing outer layer of one end of each of the support pedestals inside the counter-bored hole to stabilize the support pedestals against lateral acceleration forces. Preferably, the reinforcing outer layer comprises a carbon-carbon composite (C—C) and the inner core comprises graphite. In another embodiment, the stabilizing means is a pedestal support system to secure at least two support pedestals to each other.

It is to be understood that both the foregoing general description and the following detailed description are exemplary and explanatory only and are intended to provide further explanation of the present invention, as claimed.

### BRIEF DESCRIPTION OF THE DRAWINGS

FIG. 1 is a cross-sectional view of a crystal growth furnace of the present invention comprising a crucible block supported by three support pedestals.

FIG. 2 is a cross-sectional view of a section of the furnace of FIG. 1 showing a support pedestal recessed in a counter-bored hole in the crucible block.

FIG. 3 is an isometric view of an embodiment of the crystal growth furnace of the present invention having a pedestal support system comprising a T-shaped brace.

FIG. 4 is a cross-sectional view of an embodiment of the crystal growth furnace of the present invention having a pedestal support system comprising a brace plate with tie rods joining the brace plate to the inner furnace wall.

FIG. 5 are tables comparing the stress capacity to seismic load ratio for various furnace configurations under IBC, China and Taiwan building codes.

### DETAILED DESCRIPTION OF THE INVENTION

The present invention relates to a crystal growth furnace having at least three support pedestals and at least one means of stabilizing them as well as to a method of stabilizing the support pedestals.

The crystal growth furnace of the present invention is a high-temperature furnace capable of heating and melting a solid feedstock, such as silicon, at temperatures generally greater than about 1000° C. and subsequently promoting resolidification of the resulting melted feedstock material to form a crystalline ingot, such as a multicrystalline silicon ingot. For example, the crystal growth furnace can be a directional solidification system (DSS) crystal growth furnace. The material to be melted is at least feedstock material, for example, polysilicon feedstock, although a seed crystal can be used in conjunction with feedstock material, for example, a monocrystalline silicon seed, if a crystalline material that is monocrystalline or substantially monocrystalline is desired. For the purpose of the discussions that follow, the term feedstock refers to feedstock material or feedstock material in conjunction with a seed.

The crystal growth furnace of the present invention comprises a crucible containing feedstock material to be melted on a crucible block in the hot zone of the furnace supported from below by at least three support pedestals resting on the inner furnace wall. The hot zone of the crystal growth apparatus is an interior region within the furnace in which heat can be provided and controlled to melt and re-solidify a feedstock material in a crucible. The hot zone is surrounded by and defined by insulation which can be any material known in the art that possesses low thermal conductivity and is capable of withstanding the temperatures and conditions in a high temperature crystal growth furnace. For example, the hot zone can be surrounded by insulation of graphite. The shape and dimension of the hot zone can be formed by a plurality of insulation panels which can either be stationary or mobile. For example, the hot zone may be formed of top, side, and bottom insulation panels, with the top and side insulation panels configured to move vertically relative to a crucible placed within the hot zone. Other insulation dimensions may be used depending on the furnace hot zone shape, for example, cylindrical insulation would typically surround a cylindrical “hot zone” to conserve space in the furnace. The hot zone also comprises at least one heating system, such as multiple heating elements to provide heat to melt a solid feedstock placed in the crucible. For example, the hot zone can comprise a top heating element, positioned horizontally in the upper region of the hot zone above the crucible, and at least one side heating element positioned vertically below the top heating element and along the sides of the hot zone and the crucible. The temperature in the hot zone may be increased to melt feedstock material and then reduced to aid in its re-solidification by regulating the power provided to the various heating elements.

The hot zone further comprises a crucible, optionally within a crucible box, atop a crucible block in the hot zone. Preferably, the crucible is non-rotatable and is not moved. The crucible can be made of various heat resistant materials, for example, quartz (silica), graphite, molybdenum, silicon carbide, silicon nitride, composites of silicon carbon or silicon nitride with silica, pyrolytic boron nitride, alumina, or zirconia and, optionally, may be coated, such as with silicon nitride, to prevent cracking of the ingot after solidification. The crucible can also have a variety of different shapes having at least one side and a bottom, including, for example, cylindrical, cubic or cuboid (having a square cross-section), or tapered. Preferably, when the feedstock is silicon, the crucible is made of silica and has a cube or cuboid shape.

The crucible can optionally be contained within a crucible box on the crucible block, which provides support and rigidity for the sides and bottom of the crucible and is particularly preferred for crucibles made of materials that are either prone to damage, cracking, or softening, especially when heated. For example, a crucible box is preferred for a silica crucible but may be unnecessary for a crucible made of silicon carbide, silicon nitride, or composites of silicon carbide or silicon nitride with silica. The crucible box can be made of various heat resistant materials, such as thermally conductive high density graphite, and typically comprises at least one side plate and a bottom plate, optionally further comprising a lid. For example, for a cube or cuboid-shaped crucible, the crucible box is preferably also in the shape of a cube or cuboid, having four walls and a bottom plate, with an optional lid.

The crucible and optional crucible box are provided on top of a crucible block within the hot zone, and, as such, are in thermal communication with each other so that heat can be conducted from one to the other, preferably by direct thermal contact. The crucible block can be made of any heat resistant material and is preferably a similar material to the crucible box, if used. For example, the crucible box and crucible block are typically made of high density graphite material that is thermally conductive.

The crucible block can be raised on at least three support pedestals in order to place the crucible into a central position in the crystal growth furnace. The support pedestals can be made of any material known in the art that is capable of withstanding the temperatures and conditions in the furnace, including, for example, high density graphite. Various sizes, shapes, diameters and numbers of support pedestals are contemplated by the present invention, the diameter and number typically depending on the load weight to be supported and the interior size of the furnace. The support pedestal can be in the range of from about 50 mm to about 100 mm in diameter, such as from about 75 mm to about 95 mm. The support pedestals have an inner wall end and a crucible block end. The inner furnace wall end of the support pedestal is configured to have a bottom surface that can sit vertically flush on the inner furnace wall below the crucible block, for example, a flat surface, and can be held in place by a variety of means known in the art including, for example, by seating in a receptacle in communication with the inner furnace wall that is sized and shaped to receive the pedestal securely. The crucible block end of the support pedestal can be configured in various sizes, shapes and diameters known in the art and is preferably secured into a hole in the bottom of the crucible block. For example, the crucible block end of the support pedestal can have a pilot-pin configuration.

As discussed above, due to the ever increasing feedstock loads placed in a crucible upon the crucible block, the crystal growth furnace of the present invention further comprises at least one means of stabilizing the support pedestals. In a first embodiment, the stabilizing means is a support pedestal having a reinforcing outer layer bonded to an inner core and a crucible block comprising at least three counter-bored holes sized and shaped to recess the reinforcing outer layer of one end of each of the support pedestal into it, thereby stabilizing the pedestal. Preferably, the reinforcing outer layer is a carbon-carbon composite (C—C) outer layer and the inner core comprises graphite. The C—C outer layer can be any thickness but is preferably from about 5 mm to about 12 mm thick and more preferably from about 5 mm to about 10 mm thick. The reinforcing C—C outer layer can partially or fully cover the support pedestal along its vertical axis; preferably the reinforcing C—C outer layer fully covers the support pedestal.

For this first embodiment, the crucible block has at least three holes to receive each of the support pedestals. The holes are sized and shaped depending on the size and shape of the crucible block end of the support pedestals. The holes can vary in shape and depth depending on the thickness of the crucible block and the configuration of the crucible block end of the support pedestal. For example, when the crucible block end has a pilot-pin configuration, the hole in the crucible block is typically at least about ½ the thickness of the crucible block and the hole is further counter-bored to receive the outer diameter of the support pedestal into it. The hole can be counter-bored to a depth of from about 10 mm to about 50 mm so that the outer diameter of the support pedestal can be recessed inside the crucible block, enabling the pedestal to more readily resist sudden lateral or horizontal acceleration forces at the recess point. Preferably, the hole is counter-bored to a depth of about 15 mm.

In a second embodiment, the stabilizing means is a pedestal support system to secure and stabilize at least two support pedestals relative to one another. The pedestal support system can comprise at least one brace and at least one fastener to secure each of the at least two support pedestals to it. The brace can be fashioned from a single piece of material, or can be formed by assembling smaller pieces of material together. The brace and fasteners can be made of any material known in the art so long as the material is capable of withstanding the temperatures and conditions in the furnace, for example, high density graphite, and preferably high density graphite comprising a C—C outer layer bonded to it to strengthen it. More than one brace can be used to secure the support pedestals. For example, where three support pedestals are to be secured by a pedestal support system, one brace can be used to secure the first pedestal to the second pedestal, another brace can be used to secure the second pedestal to the third pedestal and yet another brace can be used to secure the third pedestal to the first pedestal, thus securing all three support pedestals to each other to collectively stabilize them. As another example, all least two support pedestals can be secured to each other using two separate horizontal flat braces. The brace is typically attached to the pedestals perpendicular to their vertical axis and can be positioned anywhere along the length of the pedestal between the inner furnace wall and the bottom of the crucible block. For example, the brace can be secured to the support pedestals at approximately the mid-point length of the pedestal.

The brace can have various shapes and sizes and can be configured to secure two or more support pedestals to an outer edge of the furnace or internally to each other, depending on the number of support pedestals to be employed in the furnace. For example, the pedestal support system can comprise a T-brace configured to secure the at least three support pedestals to it and each other. A notch, sized and shaped to conform to the outer diameter of the support pedestal, can be provided at an external outer edge of each end arm of the T-brace to semi-enclose a portion of the diameter of the support pedestal, and a clamp, similarly sized and shaped to conform to the outer diameter of the support pedestal, can be placed around the pedestal and secured into the brace at either side of the notch with any fastener known in the art, for example, screws, bolts and pins. The clamp may comprise a variety of materials known in the art so long as it is a material resistant to the furnace environment. For example, the material can be high density graphite and is preferably high density graphite with a C—C outer layer bonded to it. Alternatively, the support pedestal may comprise an opening which aligns with a hole in the notch of the brace through which a fastener can be passed to secure the support pedestal in the notch without the need for a clamp. Other braces used to secure support pedestals to an outer external edge are contemplated and may vary in number, thickness, shape and dimension so long as the brace is sufficiently thick to accommodate fasteners to attach the support pedestals to the brace, and the brace provides lateral support. Preferably, the thickness of the brace is greater than or equal to one diameter of the support pedestal, such as from about 50 mm to about 100 mm and preferably from about 75 mm to about 95 mm.

As another example, the pedestal support system can comprise at least one flat brace having at least two internal openings sized and shaped to receive at least two of the support pedestals through it, and fasteners to secure the support pedestals to the brace. For example, the flat brace can comprise a horizontal brace plate. The brace plate can be made of any material known in the art so long as the material is capable of withstanding the temperatures and conditions in the furnace, for example, high density graphite and preferably high density graphite comprising a C—C outer layer bonded to it. The brace plate can be fashioned from a single piece of material or can be formed by securing smaller pieces of material together to form a single flat plate. Each of the support pedestals can be secured to the brace at each of the openings with at least one fastener, such as a clamp.

For this second embodiment, the pedestal support system may further comprise at least one tie-rod for securing the pedestal support system to the inner furnace wall. For example, one end of a tie-rod can be affixed to a brace plate of the pedestal support system and the other end affixed to an anchor point on the inner furnace wall to stabilize the brace plate that secures the support pedestals. Preferably, at least two tie-rods are employed and positioned in the x and y axes of the brace to stabilize it in two directions. The tie-rods can be adjustable in length and can be made of any material known in the art so long as the material is capable of withstanding the temperatures and conditions in the furnace, for example, high density graphite and preferably, high density graphite comprising a C—C outer layer bonded to it.

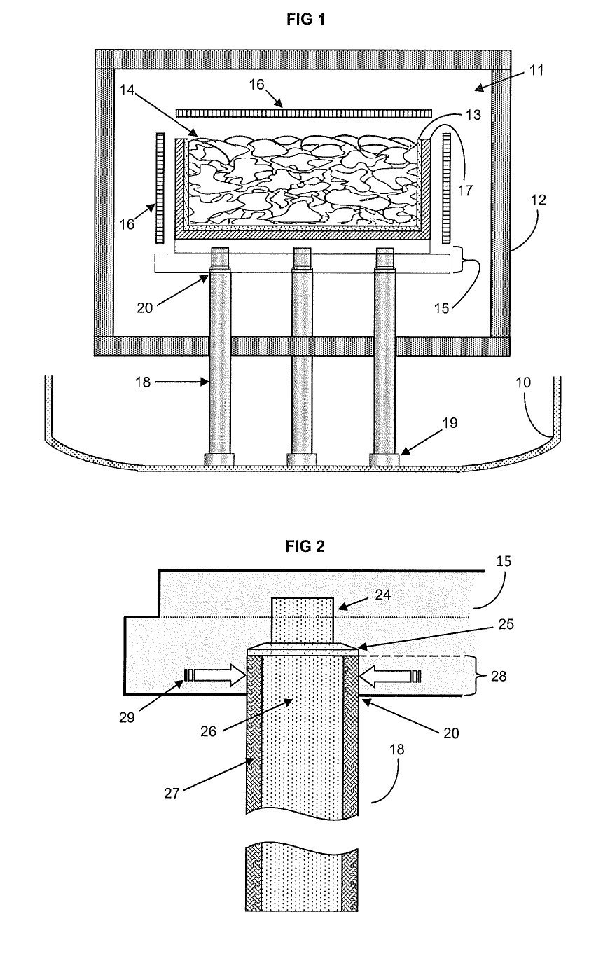

Specific embodiments of the crystal growth furnace of the present invention are shown in FIG. 1-FIG. 4 and discussed below. However, it should be apparent to those skilled in the art that these are merely illustrative in nature and not limiting, being presented by way of example only. Numerous modifications and other embodiments are within the scope of one of ordinary skill in the art and are contemplated as falling within the scope of the present invention. In addition, those skilled in the art should appreciate that the specific configurations are exemplary and that actual configurations will depend on the specific system. Those skilled in the art will also be able to recognize and identify equivalents to the specific elements shown, using no more than routine experimentation.

FIG. 1 shows a cross-sectional view of the crystal growth furnace of the present invention comprising an inner furnace wall 10 and a hot zone 11 surrounded and defined by insulation 12. The hot zone further comprises a crucible 13 containing feedstock 14 atop a two-step crucible block 15 and support pedestals 18 to support the crucible block from below. As shown in FIG. 1, at least one heating element 16 can be positioned above and along the sides of crucible 13 to melt feedstock in the crucible, for example, silicon or alumina oxide-based feedstock, before solidifying the molten material into crystalline ingots, for example, crystalline silicon or sapphire ingots, respectfully. As shown, at least three support pedestals 18 support the crucible block 15 from below. The support pedestals are vertically oriented along their axes and generally equally distributed relative to each other to provide maximum weight support appropriate for the size of the crucible block and feedstock weight. For example, where three support pedestals are used, the support pedestals may be employed in a triangular distribution. The use of more than three support pedestals in various spatial distributions is contemplated depending on the feedstock weight, the size of the crucible block, and furnace space constraints. Support pedestals 18 have a circular cross-sectional shape, although the present invention also contemplates using support pedestals having various outer diameters and shapes.

FIG. 1 also shows one end of the support pedestals held on top of the inner furnace wall 10 in receptacles, for example, conical cups 19, aligned with recessed holes 20 in the crucible block where the other end of the support pedestal is secured to maintain its vertical alignment and support the crucible block. Conical cups 19 are affixed to the inner furnace wall directly or indirectly, for example, on a thin plate attached to the inner furnace wall. Also, conical cups 19 may be made of any material known in the art that is compatible with the furnace environment outside of the hot zone, and may vary in height, size and shape to accommodate the size and shape of the inner furnace wall end of the support pedestal so long as it secures and maintains its vertical alignment with the recessed holes in the crucible block. Other means known in the art to secure the support pedestals to the inner furnace wall are also contemplated by the present invention, including, for example, clamping the support pedestals to a clamping point on the inner wall surface, so long as they hold the support pedestal in alignment with the recessed holes in the crucible block above it.

FIG. 2 shows a cross-sectional view of a section of the furnace of FIG. 1 showing a support pedestal recessed in a counter-bored hole in the crucible block. The figure shows support pedestal 18 positioned in a recessed hole 20 in crucible block 15 that is sized and shaped to accommodate the size and shape of the crucible block end of support pedestal 18. The crucible block end of support pedestal 18 has a pilot-pin 24 and is configured to secure the pedestal into the block to support the weight of crucible block 15 on the pilot-pin. The length, width and shape of pilot pin 24 can vary. The pilot-pin can have a square shape when viewed from the side having an angle that is about 90° to the top of the outer diameter of the support pedestal. Alternatively, pilot-pin 24 may have a beveled base 25 on top of support pedestal 18 as shown. Other sizes, shapes, and dimensions of pilot-pin 24 are contemplated by the present invention so long as the dimensions provide sufficient support for the weight of the load. Support pedestal 18 comprises a high density graphite core 26 that may be thermally matched with the graphite crucible block to minimize thermal expansion mismatches. The high density graphite has a carbon-carbon composite (C—C) layer 27 bonded to support pedestal 18. Various thicknesses of C—C layer 27 are contemplated by the present invention. Recessed hole 22 is counter-bored to receive support pedestal 18 into crucible block 15. Various diameters, shapes and depths of the counter-bored hole are contemplated so long as the dimensions match the outer diameter of support pedestal 18 and pilot-pin 24 and may be created by various means known in the art, including, for example, by using a circular counter-bore tool to create a circular counter-bored hole. Recessed hole 22 can be counter-bored into the crucible block bottom to various depths, including, for example approximately greater than ½ of the thickness of crucible block 15. Other depths are contemplated by the present invention. As shown, the pilot-pin fits securely in the pilot-pin hole to support the weight on the crucible block on it and the outer diameter of support pedestal 18 is recessed into the counter-bored hole to a recess depth 28 of at least about 10 mm, and preferably, 15 mm, to counter sudden lateral acceleration load forces depicted by arrows 29.

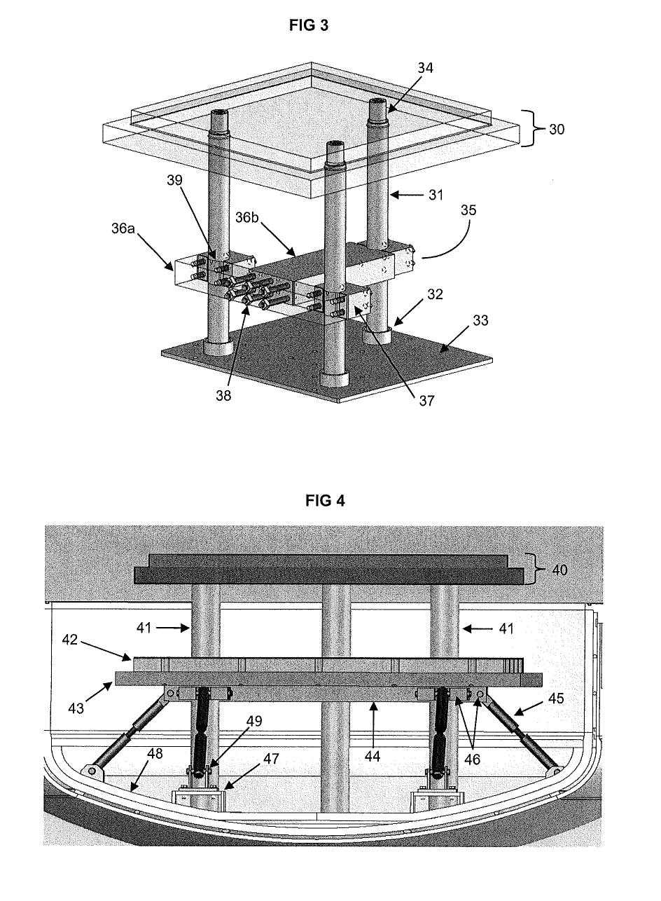

FIG. 3 shows an embodiment of the crystal growth furnace of the present invention wherein equally distributed support pedestals 31, vertically secured at one end by conical cups 32 on a plate 33 on the inner furnace wall and at the other end by recessed holes 34 in the crucible block 30, are further secured by a pedestal support system. In this example, the pedestal support system comprises T-brace 35 and fasteners to secure three support pedestals to the brace to collectively stabilize the support pedestals as shown. T-brace 35 is horizontally positioned along the vertical axis of support pedestals 31 to stabilize them relative to one another. The height of the brace along the length of the support pedestal can vary relative to the bottom of the crucible block so long as the brace provides sufficient resistance to sudden lateral acceleration loading. Typically, as shown, T-brace 35 is attached at approximately the mid-length of the support pedestals. In addition, T-brace 35 typically comprises the same graphite material used for support pedestals and can have a carbon-carbon composite (C—C) outer layer bonded to it, although other materials known in the art may be used so long as they are capable of withstanding the temperatures and conditions in the furnace. As shown, T-brace 35 is sufficiently thick enough to secure the support pedestals to it with fasteners and it is laterally rigid to stabilize and preserve the vertical alignment of the support pedestals.

T-brace 35 is formed from multiple pieces of material, although it can also be prepared from a single piece having the desired shape. Fasteners 38 are used to join material pieces 36a and 36b together to form the “T” shape, which can be made of graphite or graphite having a C—C outer layer. Various fasteners known in the art can be used, including, for example, screws, bolts and pins. Support pedestals 31 are secured externally to T-brace 35 in notches 39 provided on the outside edge of the brace. The notches are sized and shaped to receive the outer diameter of the support pedestal. The support pedestals are secured into notch 39 on the outer edge of each T-shaped extension with clamps 37 sized and shaped to surround the support pedestal and fasteners 38 to secure each side of clamp 37 to T-brace 35. Alternatively, support pedestals 31 can comprise an opening aligned with a hole in notch 39 of brace 35 wherein a fastener 38 is passed through to secure the support pedestal into the notch without the need for clamp 37.

FIG. 4 shows a crystal growth furnace of the present invention in which a pedestal support system comprising a flat brace plate 44 is used. As shown, two support pedestals 41 are secured to brace plate 44 below bottom furnace insulation layers 42 and 43 of the furnace hot zone. Brace plate 44 has at least two openings sized and shaped to allow each support pedestal 41 to pass through before being secured at one end to inner furnace wall 48 and at the opposite end into recessed holes provided in crucible block 40 as previously discussed above. Support pedestals 41 can be secured to brace plate 44 at each opening with at least one fastener (not shown), including, for example, with a set ring immediately above and below the opening in the brace plate sized and shaped to the outer dimension of the support pedestal or with a clamp secured to the brace plate and the support pedestal. Other means of fastening the support pedestal known in the art are contemplated by the present invention. As shown, brace plate 44 is rectangular, although other shapes and dimensions can be used, and it is horizontally positioned at a point approximately ½ the length of the support pedestals to secure the support pedestals internally to it. Alternatively, brace plate 44 can also be configured so that the support pedestals can be attached to an outside edge on the brace plate. The brace plate typically comprises the same graphite material used for support pedestals and can have a carbon-carbon composite (C—C) outer layer bonded to it, although other materials known in the art may be used so long as they are capable of withstanding the temperatures and conditions in the furnace.

As shown in FIG. 4, brace plate 44 can be further secured to inner furnace wall 48 with four tie-rods 45. One end of the tie-rod is affixed to an edge of brace plate 44 with an upper cotter pin assembly 46 and the other end is similarly affixed to weld pad 47 with lower cotter pin assembly 49. Tie-rod 45 is variable in length and thus can be adjusted to firmly secure brace plate 44 to the inner furnace wall 48. Other means of securing brace plate 44 to the inner furnace wall 48 are contemplated by the present invention so long as they result in stabilizing brace plate 44 securing support pedestals 41 from sudden lateral acceleration loads.

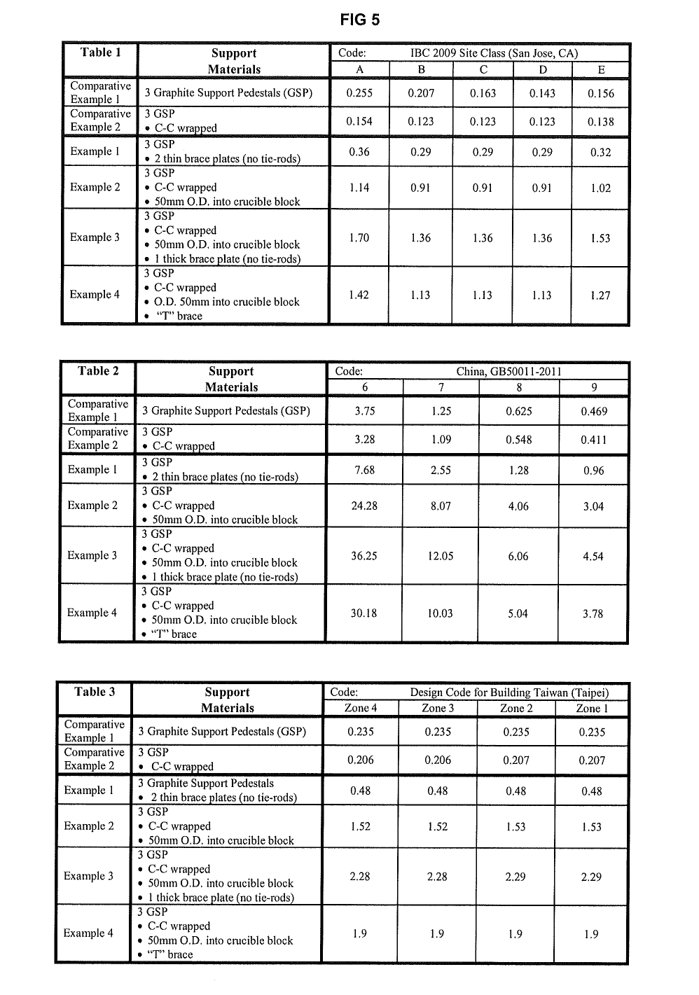

The means for stabilizing the support pedestals of the crystal growth furnace of the present invention have been found to dramatically increase the tolerance of the support pedestals supporting the crucible block to sudden lateral acceleration forces generated by certain events, including, for example, earthquakes, compared to furnaces without these stabilizing means. FIG. 5 displays computer simulation values representing the ratio of the stress capacity of the materials of construction to the seismic load applied for different configurations of the present invention as it relates to building codes for five seismic load categories of the IBC 2009 Site Class (San Jose, Calif.) (Table 1), four seismic load categories of the Chinese GB50011-2011code (Table 2) and four seismic load categories of the Design Code for Building for Taiwan (Taipei) (Table 3). Where the modeled values displayed in the tables of FIG. 5 are greater than or equal to 1, the stress capacity of the support material is greater than or equal to the seismic load applied to it and so it would not be expected to fail under that seismic load category. Referring to FIG. 5, the results in Table 1 show that in Comparative Example 1 where the outer diameter of three support pedestals, made of graphite (only), are not recessed into the crucible block, the ratio for categories A-E range from 0.143-0.255 (i.e. a value less than or equal to 1). Similarly, the results for Comparative Example 2 show that when three support pedestals comprising a C—C outer layer bonded to an inner core of graphite are used but not recessed into the crucible block, the ratio for categories A-E range from 0.123-0.154 (i.e. a value less than or equal to 1). As such, the results for Comparative Examples 1 and 2 show that where only the pilot-pin on the three graphite support pedestals or the three C—C bonded graphite support pedestals are inserted into the crucible block, the stress capacity was less than the seismic load applied and therefore, the support pedestals were prone to structural failure.

By comparison, Example 1 in Table 1 shows that when three non-recessed graphite support pedestals are secured by a brace, in this case two thin (12 mm) brace plates separated by 25 mm, the stress capacity to seismic load ratio showed improvement over the results for Comparative Example 1, even though the ratio observed was still <1. However, the results in Example 2 of Table 1 surprisingly show that when three graphite support pedestals having an outer diameter of three C—C bonded graphite support pedestals are recessed approximately 50 mm into the crucible block, the stress capacity to seismic load ratio dramatically increases compared to the results for three non-recessed C—C bonded graphite support pedestals of Comparative Example 2, even in the absence of bracing. In fact, the results in Table 1 show a ratio of ≧1 for categories A and E when reviewed in the light of the IBC 2009 code for these categories. Furthermore, a value nearly approaching 1 was determined for categories B, C and D. Additionally, results of ≧1 were observed in Example 2 for all categories in Tables 2 and 3, further demonstrating the importance of recessing support pedestals to reduce the effect of lateral acceleration force.

Even more surprising results were observed when C—C bonded recessed support pedestals were secured with a brace plate (without tie-rods) or a T-brace as the stabilizing means. The results show that the combination of recessing three C—C bonded support pedestals into the crucible block and securing the three recessed support pedestals to a brace, meets or exceeds all five categories of the IBC 2009 Site Class (San Jose, Calif.), all four categories of the Chinese GB50011-2011 and all four categories of the Design Code for Building for Taiwan (Taipei), even without further stabilization afforded by utilizing tie-rods. Referring again to Table 1 in FIG. 5, the results show in Example 3 that when three C—C bonded graphite support pedestals are recessed approximately 50 mm into the crucible block and secured by a brace plate 40 mm thick, the ratio for categories A-E range from 1.36-1.70 (i.e. a value greater than or equal to 1). Similarly, in Example 4 in which three C—C wrapped graphite support pedestals are recessed approximately 50 mm into the crucible block and secured by a T-brace, the ratio for categories A-E range from 1.13-1.42 (i.e. a value greater than or equal to 1). The results in Examples 3 and 4 demonstrate that when the holes in the crucible block are counter-bored and approximately 50 mm of the outer diameter of the C—C bonded graphite support pedestals are recessed into the crucible block, and the recessed support pedestals are further secured by a brace, the ratio of the material's stress capacity to seismic load is ≧1 when reviewed in light of the five seismic load categories of the IBC 2009 Site Class (San Jose, Calif.). As such, the support pedestals would not be expected to fail under the seismic load for these categories. The same surprising results were also observed in Table 2 for all four seismic categories of the Chinese GB50011-2011 code, and Table 3 for all four seismic categories of the Design Code for Building for Taiwan (Taipei). The results highlight the surprisingly synergistic role realized by recessing C—C bonded support pedestals and stabilizing the support pedestals with a brace. This synergy is evident in Table 1 when comparing the ratio values in Category B, C and D for Comparative Example 2 (0.123 for B, C and D), Example 2 (0.91 for B, C and D) and Example 3 (1.36 for B, C and D). The results from these examples are dramatic improvements over the Comparative Examples.

The foregoing description of preferred embodiments of the present invention has been presented for the purposes of illustration and description. It is not intended to be exhaustive or to limit the invention to the precise form disclosed. Modifications and variations are possible in light of the above teachings, or may be acquired from practice of the invention. The embodiments were chosen and described in order to explain the principles of the invention and its practical application to enable one skilled in the art to utilize the invention in various embodiments and with various modifications as are suited to the particular use contemplated. It is intended that the scope of the invention be defined by the claims appended hereto, and their equivalents.

What is claimed is:

1. A crystal growth furnace for growing a crystalline material comprising:
an inner furnace wall;
at least three support pedestals resting on top of the inner furnace wall; and
a crucible block supported from below by the at least three support pedestals, wherein at least two support pedestals are secured to each other by a pedestal support system.

2. The crystal growth furnace of claim 1, wherein at least three support pedestals comprise a reinforcing outer layer bonded to an inner core.

3. The crystal growth furnace of claim 2, wherein the reinforcing outer layer comprises a carbon-carbon composite.

4. The crystal growth furnace of claim 2, wherein the inner core comprises graphite.

5. The crystal growth furnace of claim 1, wherein the at least three support pedestals comprise graphite.

6. The crystal growth furnace of claim 1, wherein the crucible block comprises at least three recessed holes sized and shaped to receive one end of the at least three support pedestals.

7. The crystal growth furnace of claim 1, wherein the pedestal support system comprises at least one brace and at least one fastener.

8. The crystal growth furnace of claim 7, wherein the at least one fastener is configured to secure each of the at least two support pedestals to the at least one brace.

9. The crystal growth furnace of claim 7, wherein the at least one brace, fasteners or both comprise graphite.

10. The crystal growth furnace of claim 7, wherein the at least one brace comprises at least two openings sized and shaped to receive each of the at least two support pedestals therethrough, each of the support pedestals being secured to the at least one brace at each opening with at least one fastener.

11. The crystal growth furnace of claim 7, wherein the at least one brace comprises at least one notch on an outside edge sized and shaped to receive each of the at least two support pedestals.

12. The crystal growth furnace of claim 11, wherein the at least two support pedestals are secured in the notch with a clamp comprising graphite that is sized and shaped to surround each of the support pedestals and the clamp is secured to the at least one brace with at least one fastener.

13. The crystal growth furnace of claim 11, wherein the support pedestal comprises an opening aligned with a hole in the notch of the at least one brace and the fastener is passed through the opening to secure the support pedestal to the notch.

14. The crystal growth furnace of claim 1, wherein the pedestal support system comprises at least one tie rod for securing the pedestal support system to the inner furnace wall.

15. The crystal growth furnace of claim 14, wherein the tie rod has an end affixed to the pedestal support system and another end affixed to the inner furnace wall.

16. The crystal growth furnace of claim 14, wherein the pedestal support system comprises at least one brace and the tie rod has an end affixed to the at least one brace and another end affixed to the inner furnace wall.

17. The crystal growth furnace of claim 14, wherein the pedestal support system further comprises at least one fastener configured to secure each of the at least two support pedestals to the pedestal support system.

18. The crystal growth furnace of claim 14, wherein the tie rod has an adjustable length.

19. The crystal growth furnace of claim 14, wherein the tie rod comprises graphite.

20. A crystal growth furnace for growing a crystalline material comprising:
an inner furnace wall;
at least three support pedestals resting on top of the inner furnace wall, wherein the at least three support pedestals comprise a reinforcing outer layer bonded to an inner core; and
a crucible block supported from below by the at least three support pedestals, wherein the crucible block comprises at least three counter-bored holes sized and shaped to recess the reinforcing outer layer of one end of each of the support pedestals inside the counter-bored hole.

21. The crystal growth furnace of claim 20, wherein the reinforcing outer layer comprises a carbon-carbon composite.

22. The crystal growth furnace of claim 20, wherein the inner core comprises graphite.

23. The crystal growth furnace of claim 20, further comprising a pedestal support system to secure at least two support pedestals to each other.

24. The crystal growth furnace of claim 23, wherein the pedestal support system comprises at least one brace and at least one fastener configured to secure each of the at least two support pedestals to the at least one brace.
